(19) United States
(12) Patent Application Publication
(10) Pub. No.: US 2020/0194649 A1
(43) Pub. Date: Jun. 18, 2020

(54) ENERGY TRANSFER STRUCTURE AND ENERGY CONVERSION DEVICE

(71) Applicant: SAMSUNG ELECTRONICS CO., LTD., Suwon-si (KR)

(72) Inventors: Eunkyung LEE, Seoul (KR); Byoung-Lyong CHOI, Seoul (KR); Hyosug LEE, Suwon-si (KR); Younsuk CHOI, Seongnam-si (KR)

(21) Appl. No.: 16/797,898

(22) Filed: Feb. 21, 2020

Related U.S. Application Data
(63) Continuation of application No. 15/197,849, filed on Jun. 30, 2016.

(30) Foreign Application Priority Data
Sep. 24, 2015 (KR) 10-2015-0135883

(51) Int. Cl. H01L 35/30

(52) U.S. Cl. CPC H01L 35/30

(57) ABSTRACT

An energy transfer structure includes an energy transfer material and a vacant space part provided in the energy transfer material where the vacant space part is provided through a region occupied with the energy transfer material or from a side of the region occupied with the energy transfer material toward an inside with a predetermined depth.

### CROSS-REFERENCE TO RELATED APPLICATION

This application is a continuation of U.S. patent application Ser. No. 15/197,849, filed on Jun. 30, 2016, which claims priority to Korean Patent Application No. 10-2015-0135883, filed on Sep. 24, 2015, and all the benefits accruing therefrom under 35 U.S.C. § 119, the content of which in its entirety is herein incorporated by reference.

### BACKGROUND

### 1. Field

Embodiments are related to an energy transfer structure and an energy conversion device including the same.

### 2. Description of the Related Art

Recently, energy harvesting technologies have drawn attention. The energy harvesting technologies are used to manufacture a thermoelectric device, for example. The thermoelectric device uses a thermoelectric conversion phenomenon. The thermoelectric conversion is an energy conversion between thermal energy and electrical energy, and herein a Seebeck effect means that electricity is generated when a thermoelectric material has a temperature difference between both terminal ends, and a Peltier effect means that a temperature gradient is generated between both terminal ends of the thermoelectric material when a current flows in the thermoelectric material and thus decreases a temperature.

The thermoelectric device may have efficiency determined by a performance coefficient of the thermoelectric material, that is, a ZT (figure of merit) coefficient, and the ZT coefficient (non-dimension) may be obtained by Equation 1.

$$ZT = \frac{{S}^{2} σ}{k} T \qquad [ Equation 1 ]$$

Herein, the ZT coefficient is proportional to the Seebeck coefficient (S) and electrical conductivity (σ) of the thermoelectric material but inversely proportional to thermal conductivity (k).

In other words, as a material has larger electrical conductivity and smaller thermal conductivity, thermoelectric efficiency is improved.

### SUMMARY

When a carrier is more concentrated to improve the electrical conductivity, the thermal conductivity is also increased, in general. Accordingly, improved performance of the thermoelectric device may be limited due to a strong correlation of the factors determining the thermoelectric efficiency.

One embodiment is to realize efficient energy transfer performance by weakening the strong correlation between the thermal conductivity and the electrical conductivity.

Another embodiment provides an energy transfer structure including an energy transfer material and a vacant space part defined inside the energy transfer material, where the vacant space part is provided through a region occupied with the energy transfer material or from the side of the region with the energy transfer material toward the inside with a predetermined depth.

In an embodiment, the vacant space part may be defined by a pore, a porous channel, or a combination thereof.

In an embodiment, the vacant space part may be provided in plural through the region occupied with the energy transfer material in a vertical direction.

In an embodiment, a plurality of the vacant space part may have a cross section shape of a circle, a radial shape, a polygon, or a combination thereof.

In an embodiment, a plurality of the vacant space part may have a cross section shape of which a longest length ranges from several nanometers to several micrometers.

In an embodiment, the region where a plurality of the vacant space part is not provided out of the region occupied with the energy transfer material may have a tube-shaped cross section.

In an embodiment, the vacant space part may be defined in plural from the side of the region occupied with the energy transfer material toward the inside, and the region occupied with the energy transfer material may be partially column-shaped by a plurality of the vacant space part.

In an embodiment, the column-shaped region may have a cross section shape of which a longest length ranges from several nanometers to several micrometers.

In an embodiment, the column-shaped region may have a cross section shape such as a circle, a radial shape, a polygon, or a combination thereof.

In an embodiment, the column-shaped region may be provided in plural, and a bridge may be provided among a plurality of the column-shaped regions.

In an embodiment, the energy transfer material may include a bulk-phased material.

In an embodiment, the energy transfer material may include an organic polymer, an inorganic polymer, a semiconductor material, or a combination thereof.

In an embodiment, the energy transfer structure may have a cross section shape of which a longest length is greater than or equal to several micrometers.

According to another embodiment, an energy conversion device including the energy transfer structure is provided.

The energy conversion device may include a thermoelectric device, a solar cell, or a photo-sensing device.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 shows a part of the cross section of an embodiment of an energy transfer structure;

FIG. 2 is a schematic view showing an embodiment of an energy transfer structure;

FIG. 3 is a cross-sectional view showing the energy transfer structure of FIG. 2;

FIG. 4 is a cross-sectional view showing another embodiment of an energy transfer structure;

FIG. 5 is a cross-sectional view showing another embodiment of an energy transfer structure;

FIG. 6 is a cross-sectional view showing another embodiment of an energy transfer structure;

FIG. 7 is a cross-sectional view showing another embodiment of an energy transfer structure;

FIG. 8 is a cross-sectional view showing another embodiment of an energy transfer structure;

FIG. 9 is a cross-sectional view showing another embodiment of an energy transfer structure;

FIG. 10 is a cross-sectional view showing another embodiment of an energy transfer structure;

FIG. 11 is a cross-sectional view showing another embodiment of an energy transfer structure;

FIG. 12 is a cross-sectional view showing another embodiment of an energy transfer structure; and

FIG. 13 is a SEM image showing an embodiment of the porous structure of the energy transfer structure.

### DETAILED DESCRIPTION

Exemplary embodiments will hereinafter be described in detail, and may be easily performed by those who have common knowledge in the related art. However, this disclosure may be embodied in many different forms and is not construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. In an exemplary embodiment, when the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, when the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. In an exemplary embodiment, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

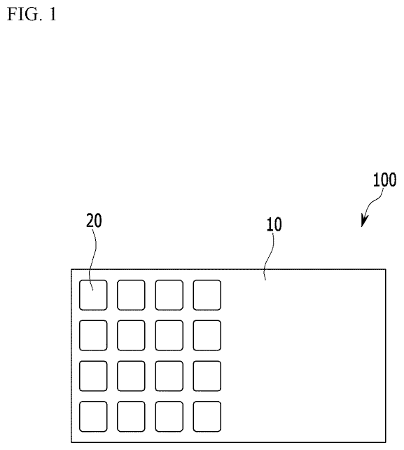

Hereinafter, an energy transfer structure according to one embodiment is described with reference to FIG. 1.

FIG. 1 shows a part of the cross section of the energy transfer structure according to the embodiment. Referring to FIG. 1, an energy transfer structure 100 according to one embodiment includes an energy transfer material 10 and a vacant space part 20 defined in the energy transfer material 10.

The energy transfer material 10 includes a material transferring all kinds of energy such as thermal energy, light energy, electrical energy, and the like and may be, for example, a bulk-phased material. In an embodiment, the energy transfer material 10 may include, for example, an organic polymer, an inorganic polymer, a semiconductor material, or a combination thereof, for example, a Group IV semiconductor material, a Group III-V semiconductor material, a Group II-VI semiconductor material, and for another example, various oxides and/or nitrides, but is not limited thereto.

The vacant space part 20 is defined through a region occupied with the energy transfer material 10 or from the side of the region occupied with the energy transfer material 10 toward the inside with a predetermined depth.

In an embodiment, the vacant space part 20 may be defined by a pore, a porous channel, or a combination thereof.

The pore and the porous channel are not limited in terms of a size. A combination of the pore and the porous channel has no limit, and for example, the vacant space part 20 may have a structure that a pore is provided at the side of the porous channel.

The vacant space part 20 may be variously defined inside the energy transfer material 10. In an embodiment, the vacant space part 20 may be vertically or diagonally defined inside the energy transfer material 10, for example, but is not limited thereto.

According to one embodiment, the energy transfer structure 100 distributes the vacant space part 20 such as a pore or a porous channel along the energy transfer material 10 and thus may largely reduce thermal conductivity, since a region that the vacant space part 20 is distributed (i.e., the left side of the energy transfer structure 100 in FIG. 1) plays a role of strong scattering during a movement of electrical carriers or phonons. On the contrary, the other region that the vacant space part 20 is not distributed (i.e., the right side of the energy transfer structure 100 in FIG. 1) plays a role of passing carriers or phonons and may secure electrical conductivity in a predetermined level.

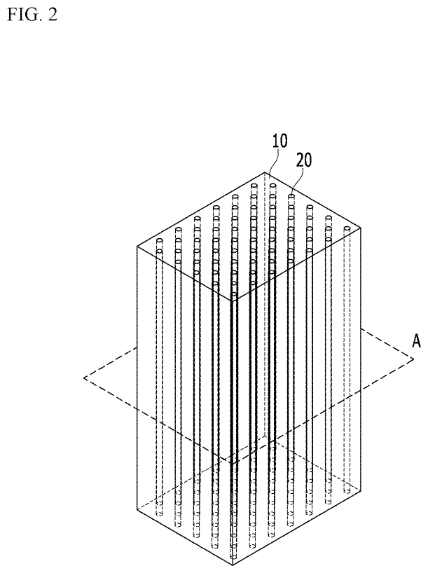

Hereinafter, the energy transfer structure according to one embodiment is illustrated in FIGS. 2 to 5.

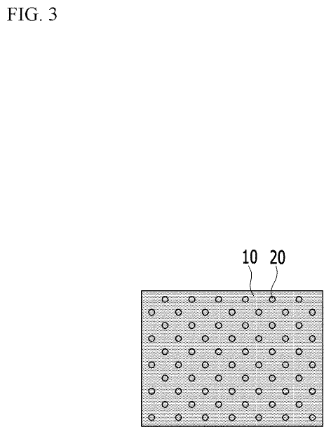

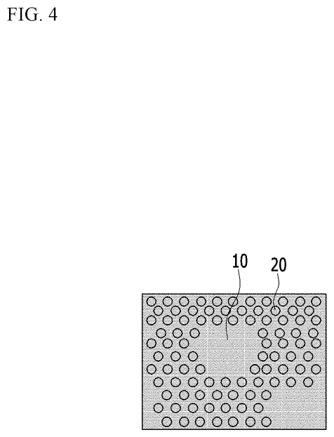

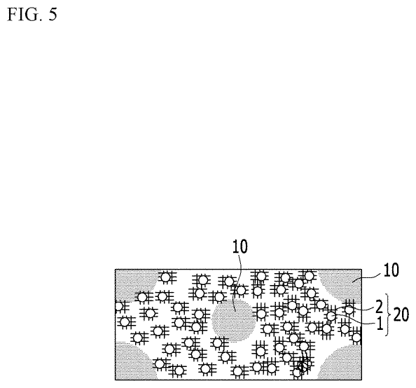

FIG. 2 is a schematic view showing the energy transfer structure according to one embodiment, and FIG. 3 is a cross sectional view of the energy transfer structure of FIG. 2 by cutting it along an incision surface A. FIG. 4 is a cross-sectional view showing an energy transfer structure according to another embodiment, and FIG. 5 is a cross-sectional view showing the energy transfer structure according to another embodiment.

Referring to FIGS. 2 and 3, the vacant space part 20 is defined through a region occupied with the energy transfer material 10 in a vertical direction all over the region occupied with the energy transfer material 10.

Referring to FIG. 4, the vacant space part 20 is defined through the region occupied with the energy transfer material 10 as shown in FIG. 3 but through a part of the region occupied with the energy transfer material 10 unlike FIG. 3. In other words, the vacant space part 20 is not defined in the other region occupied with the energy transfer material 10.

Referring to FIGS. 3 and 4, the vacant space part 20 is defined as a porous channel through a region occupied with the energy transfer material 10. The porous channel is regularly arranged like a honeycomb or irregularly arranged.

Referring to FIG. 5, the vacant space part 20 as shown in FIG. 4 is defined through a part of the region occupied with the energy transfer material 10, but herein, the vacant space part 20 has a structure that a porous channel 1 is combined with a pore 2 unlike FIG. 4. In FIG. 5, the vacant space part 20 has a structure that the pore is provided at the side of the porous channel 1. This structure may further suppress conductivity of phonon by roughening an interface between the energy transfer material 10 and the vacant space part 20.

Referring to FIGS. 2 to 5, the vacant space part 20 may be defined in plural inside the energy transfer material 10, and a plurality of the vacant space part 20 may have a cross section shape of, for example, a circle, a polygon such as a triangle, a quadrangle, a pentagon, a hexagon, or the like, or a radial shape but is not limited thereto. In an embodiment, a plurality of the vacant space part 20 may respectively have a cross section shape of which a longest length ranges from several nanometers to several micrometers, for example, in a range of about 1 nanometer to about 5 micrometers, but is not limited thereto.

In this way, the energy transfer structure according to one embodiment has the vacant space part 20 such as a pore or a porous channel defined in a predetermined shape inside the energy transfer material 10. Accordingly, when electrical carriers or phonons move inside the energy transfer material 10, the electrical carriers or phonons may be strongly scattered by the vacant space part 20, efficiently reducing thermal conductivity. In addition, the phonons may hardly move through vacant space part 20, further reducing the thermal conductivity.

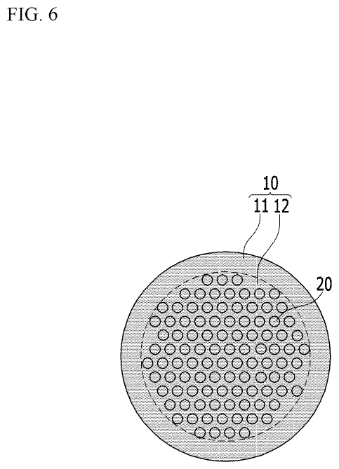

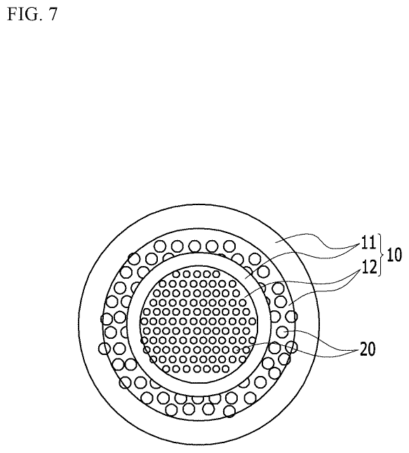

FIG. 6 is a cross-sectional view showing an energy transfer structure according to still another embodiment, and FIG. 7 is a cross-sectional view showing the energy transfer structure according to the embodiment.

In the energy transfer structure shown in FIGS. 6 and 7, a region 11 that a plurality of vacant space part 20 is not defined in an outer side of a region occupied with the energy transfer material 10 has a tube-shaped cross section. In other words, the vacant space part 20 is defined in the region 12 except for the tube shaped region provided in an outer side of the region occupied with energy transfer material 10. The energy transfer structure shown in FIG. 7 has a plurality of the tube-shaped region. In FIGS. 6 and 7, the region 11 that a plurality of the vacant space part 20 is not defined in an outer side of the region occupied with the energy transfer material 10 is designed to have a tube shape but is just one example and may be modified to have various shapes in order to induce interface scattering and thus reduce thermal conductivity.

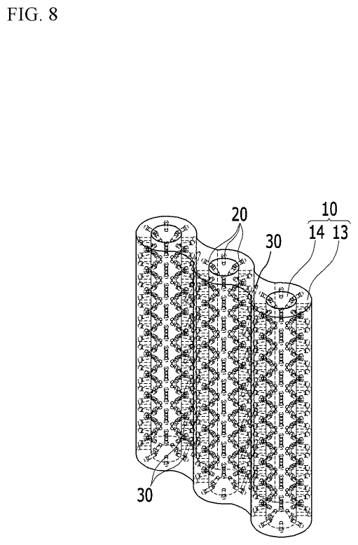

Hereinafter, an energy transfer structure according to still another embodiment is illustrated in FIGS. 8 to 12.

FIG. 8 is a side view showing an energy transfer structure according to the embodiment.

Referring to FIG. 8, the vacant space part 20 is defined in plural from the side of a region occupied with the energy transfer material 10 toward the inside. Herein, the direction from the side toward the inside is not limited but may be, for example, horizontal or diagonal.

A part of the region occupied with the energy transfer material 10 is defined as a column-shaped region 13 by a plurality of the vacant space part 20. In other words, the region 13 that a plurality of the vacant space part 20 is not defined has a column shape by a region 14 that a plurality of the vacant space part 20 is defined in an outer side of the region occupied with the energy transfer material 10.

In embodiment, the column-shaped region 13 has a cross section shape of, for example, a circle, a polygon such as a triangle, a quadrangle, a pentagon, a hexagon, or the like or a radial shape, but is not limited thereto. In an embodiment, the column-shaped region 13 has a cross section shape of which a longest length ranges from several nanometers to several micrometers, for example, of about 5 nanometers to about 1 micrometer, but is not limited thereto.

The energy transfer structure shown in FIG. 8 includes a bridge 30 provided among a plurality of the column-shaped region 13. The bridge 30 may play a role of supporting an energy transfer material in the column-shaped region 13 and include a glass material. In an embodiment, the bridge 30 may include a crystal material, for example.

When the energy transfer material is provided to have a nano size structure of the nano column shape 13, for example, the nano column shape 13 may not be maintained due to a relatively high height compared to a diameter. However, the bridge 30 is provided among the energy transfer materials in the column-shaped region 13 and thus may decrease instability due to the nano size structure.

This energy transfer structure may have a nano wire region limited by forming a pore structure at the side of the nano column after forming the nano column with the energy transfer material and forming the bridge among the nano columns. The nano wire region provided by the pore may form a structure having low thermal conductivity and maintain electrical conductivity.

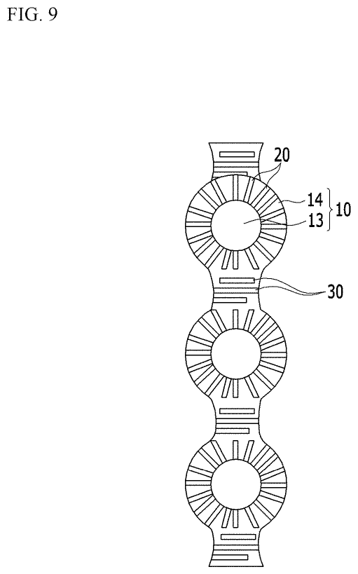

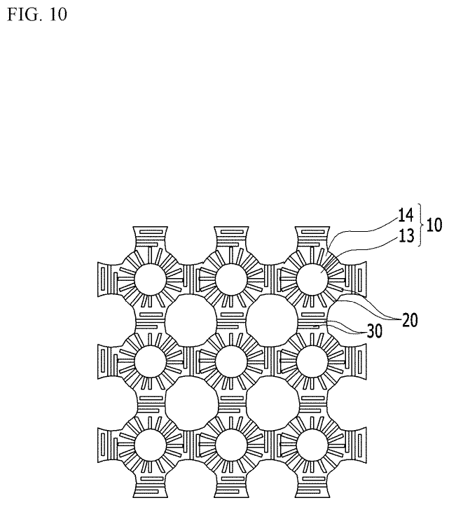

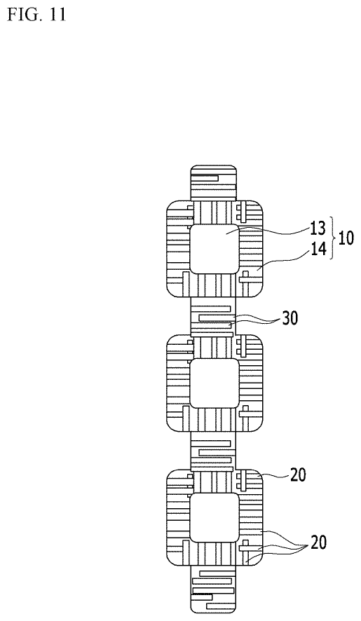

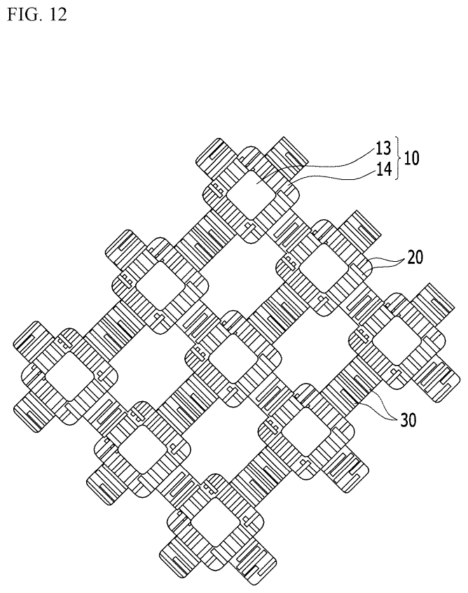

FIG. 9 is a cross-sectional view showing an energy transfer structure including the bridge according to one example, FIG. 10 is a cross-sectional view showing enlarging the energy transfer structure shown in FIG. 9, FIG. 11 is a cross-sectional view showing an energy transfer structure including the bridge according to another example, and FIG. 12 is a cross-sectional view enlarging the energy transfer structure shown in FIG. 11.

The energy transfer structures shown in FIGS. 9 to 12 have a plurality of the vacant space part 20 defined from the side of the region occupied with the energy transfer material 10 toward the inside. The region 13 that a plurality of the vacant space part 20 is not defined has a column shape by the region 14 that a plurality of the vacant space part 20 is defined in an outer side of the region occupied with the energy transfer material 10.

Referring to FIGS. 9 to 12, the bridge 30 is provided among a plurality of the column-shaped region 13 and plays a role of supporting a plurality of the column-shaped region 13 as shown in FIG. 8. The column-shaped region 13 has a circular cross section in FIGS. 9 and 10 and a quadrangular cross section in FIGS. 10 and 11, but is not limited thereto, and may be designed to have various other structures to control mobility of carriers and phonons.

The aforementioned energy transfer structure may have a cross section shape of which a longest length is greater than or equal to several micrometer, but is not limited thereto.

The aforementioned energy transfer structure may be manufactured in a metal assisted chemical etching method (e.g., Metal-assisted chemical etching of silicon and nanotechnology applications, 9, 3, 271-304, 2014) or a Reactive Ion Etching (“RIE”) method commonly used to manufacture a semiconductor, for example, but is not limited thereto.

The energy transfer structure may have a pore or a porous channel defined without a separate template. In addition, the pore or the porous channel may be controlled regarding a size or a position and have, for example, various sizes from a nano size to a bulk size.

According to another embodiment, an energy conversion device including the aforementioned energy transfer structure is provided. The aforementioned energy transfer structure may be for example applied to a thermoelectric device such as a thermoelectric generator and a thermoelectric cooler. In an embodiment, the aforementioned energy transfer structure may be applied to a photo-sensing device such as a solar cell, an electric sensor, or an image sensor, for example, but is not limited thereto.

Hereinafter, the invention is illustrated in more detail with reference to examples. However, these examples are exemplary, and the invention is not limited thereto.

### Manufacture of Porous Structure

A metal catalyst such as Ag, Au, Pt, and the like is deposited to be several to tens of nanometers on the surface of a semiconductor material such as silicon, patterned to have a desired pattern or not patterned, and dipped in a mixed solution of HF and H₂O₂, for example, so that the silicon may be reduced and removed.

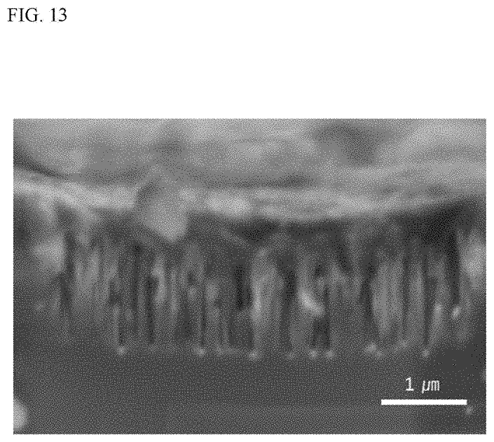

The reduced silicon is provided on the interface between the metal and the silicon, and the interface region is dissolved in the hydrofluoric acid solution and leaves a pore on the surface of the silicon. In general, the surface of the silicon is etched through a principle that a nano-sized Ag particle is attached on the surface of silicon when the silicon is dipped in a mixed solution of AgNO₃ and HF. Herein, a pore having a predetermined depth may be defined through a reduction reaction on the interface of the silicon with a fine nano-sized metal. FIG. 13 is a SEM image showing a porous structure manufactured according to the process.

Referring to FIG. 13, a several nanometer-sized porous channel is defined.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. An energy transfer structure comprising:
a plurality of pillars made of an energy transfer material;
a plurality of periphery portions each of which surrounds one of the pillars and is made of the energy transfer material; and
a plurality of bridges connecting between the periphery portions,
wherein the periphery portions respectively have a plurality of pores extending toward the pillars.

2. The energy transfer structure of claim 1, wherein the bridges respectively have a plurality of pores.

3. The energy transfer structure of claim 1, wherein the pillars have a cross-section of which longest length ranges from several nanometers to several micrometers.

4. The energy transfer structure of claim 3, wherein the pillars have a cross-section of one of a circle, a radial shape, a polygon, and any combination thereof.

5. The energy transfer structure of claim 1, wherein the pillars surrounded by the periphery portions are arranged in a line.

6. The energy transfer structure of claim 1, wherein the pillars surrounded by the periphery portions are arranged in a matrix and the bridges connect the periphery portions in row direction and column direction.

7. The energy transfer structure of claim 1, wherein the energy transfer material comprises one of an organic polymer, an inorganic polymer, a semiconductor material, and any combination thereof.

8. An energy conversion device comprising the energy transfer structure of claim 1.

9. The energy conversion device of claim 8, wherein the energy conversion device is one of a thermoelectric device, a solar cell, and a photo-sensing device.

10. The energy conversion device of claim 8, wherein the bridges respectively have a plurality of pores.

11. The energy conversion device of claim 8, wherein the pillars have a cross-section of which longest length ranges from several nanometers to several micrometers.

12. The energy conversion device of claim 11, wherein the pillars have a cross-section of one of a circle, a radial shape, a polygon, and any combination thereof.

13. The energy conversion device of claim 8, wherein the pillars surrounded by the periphery portions are arranged in a line.

14. The energy conversion device of claim 8, wherein the pillars surrounded by the periphery portions are arranged in a matrix and the bridges connect the periphery portions in row direction and column direction.

15. The energy conversion device of claim 8, wherein the energy transfer material comprises one of an organic polymer, an inorganic polymer, a semiconductor material, and any combination thereof.
